(19) United States
(12) Patent Application Publication
(10) Pub. No.: US 2026/0302061 A1
(43) Pub. Date: Oct. 1, 2026

(54) MONOLITHIC DIAMOND CAPACITOR WITH CONDUCTIVE CARBON ELECTRODES

(71) Applicant: Medtronic, Inc., Minneapolis, MN (US)

(72) Inventors: Christian S. Nielsen, River Falls, WI (US); Mark E. Viste, Brooklyn Center, MN (US); Jimmy L. Davidson, Brentwood, TN (US)

(21) Appl. No.: 19/477,290

(22) PCT Filed: Apr. 17, 2024
(86) PCT No.: PCT/US2024/024891

§ 371 Date: Oct. 21, 2025

Related U.S. Application Data
(60) Provisional application No. 63/461,037, filed on Apr. 21, 2023.

(51) Int. Cl. H01G 4/08; H01G 4/008; H01G 4/012

(52) U.S. Cl. CPC H01G 4/08; H01G 4/008; H01G 4/012

(57) ABSTRACT

Capacitors and methods of making the same are provided. The capacitors may include a monolithic diamond body with electrodes of conductive carbon therein. The electrodes of conductive carbon may be separated by a dielectric diamond layer of the monolithic diamond body. The electrodes may be formed by transforming regions of the monolithic diamond body into conductive carbon using a laser.

### TECHNICAL FIELD

This disclosure generally relates to, among other things, capacitors and, more particularly, to diamond capacitors.

### BACKGROUND

In general, there is a need for capacitor technology that can provide high voltage and high energy density. Such capacitor technology may be useful in a variety of applications and fields, such as in medical, industrial, and military applications, for just a few examples. As another example, such capacitor technology may be useful in implantable medical devices (such as cardioverter defibrillators).

Therapeutic electrical pulse delivery systems and apparatuses generally use capacitors to store energy and deliver a therapeutic pulse or shock to a patient. Capacitors may store energy in an electric field between two electrodes (e.g., a first electrode and a second electrode). Capacitors may charge and discharge stored energy more rapidly than batteries or other power sources. Additionally, capacitors can operate at a higher voltage than batteries or other power sources of a similar size. In other words, capacitors may generally be described as having a higher power density than other power sources. Accordingly, capacitors may be used to provide high voltage pulses or shocks in therapeutic electrical pulse delivery systems and apparatuses.

In a lab or hospital setting, the size, shape, weight, and durability of capacitors in therapeutic electrical pulse delivery systems may not be significant. However, size, shape, weight, and durability of capacitors are important design considerations for therapeutic electrical pulse delivery systems designed to be implanted in or worn by a patient. Large or bulky capacitors and capacitor housings may increase the size and weight of implantable and wearable devices. Furthermore, capacitors may be subject to mechanical or electromechanical deformation that can affect the operation of therapeutic electrical pulse delivery systems and apparatuses over time. Thus, capacitors and pulse generators that can deliver high voltage, high energy therapeutic pulses in a small, light-weight form factor with high durability may be desirable.

### SUMMARY

As described herein, capacitors suitable for small, light-weight form factors and increased durability can be achieved using a monolithic diamond body having capacitor unit cells formed therein by focusing electromagnetic radiation into the monolithic diamond body to convert the diamond into conductive carbon. Such capacitors may reduce the mass and volume required to achieve a given capacitance. Additionally, monolithic diamond capacitors may be designed in many different form factors and may be less susceptible to electromechanical deformation and degradation.

Embodiments disclosed herein may include a capacitor having a monolithic diamond body including a first electrode region, a second electrode region, and a dielectric diamond layer. The first electrode region may have conductive carbon extending from a first electrode contact region at an outer surface of the monolithic diamond body into the monolithic diamond body. The second electrode region may have conductive carbon extending from a second electrode contact region at the outer surface of the monolithic diamond body into the monolithic diamond body. The dielectric diamond layer of the monolithic diamond body may separate the first electrode region and the second electrode region.

The capacitor may further include a third electrode region, a fourth electrode region, and a second dielectric diamond layer of the monolithic diamond body. The third electrode layer may extend from a third electrode contact region at the outer surface of the monolithic diamond body into the monolithic diamond body. The fourth electrode region may extend from a fourth electrode contact region at the outer surface of the monolithic diamond body into the monolithic diamond body. The second dielectric diamond layer may separate the third electrode region and the fourth electrode region. The first electrode region may define a first electrode plane, and the third electrode region may define a third electrode plane parallel to the first electrode plane.

One or both of the first and second electrode regions may each define a plane. The first electrode region may define a first electrode plane and the second electrode region may define a second electrode plane parallel to the first electrode plane. The first electrode contact region may define a first electrode contact plane co-planar with the first electrode plane. One or both of the first and second electrode regions may each define a ring. The first electrode region may define a first electrode ring and the second electrode region may define a second electrode ring concentric to the first electrode ring. One or both of the first and second electrode regions may each define an axis. The first electrode region may define a first electrode axis and the second electrode region may define a second electrode axis parallel to the first electrode axis. The first electrode contact region may define a first electrode contact axis co-axial with the first electrode axis. The first electrode region and the second electrode region may be of opposite polarities. A width of the first electrode region may be greater than or equal to a width of the first electrode contact region. A thickness of the dielectric diamond layer may be between 250 nanometers and 2 micrometers. A thickness of the first electrode region and a thickness of the second electrode region may each be between 250 nanometers and 2 micrometers. A width of the monolithic diamond body may be between 2 centimeters and 6 centimeters wide. A thickness of the monolithic diamond body may be between 0.1 centimeters and 0.5 centimeters.

Embodiments described herein may further include a capacitor having a monolithic diamond body and a plurality of capacitor unit cells. Each unit cell may include a first electrode region, a second electrode rection, and a dielectric diamond layer of the monolithic diamond body. The first electrode region may include conductive carbon extending from a first electrode contact region at an outer surface of the monolithic diamond body into the monolithic diamond body. The second electrode region may include conductive carbon extending from a second electrode contact region at the outer surface of the monolithic diamond body into the monolithic diamond body. The dielectric diamond layer of the monolithic diamond body may separate the first electrode region and the second electrode region.

The first electrode region of at least one of the plurality of capacitor unit cells may be the second electrode region of another one of the plurality of capacitor unit cells. The capacitor may further include a first electrode connector electrically connecting at least two first electrode regions of the plurality of capacitor unit cells. The first electrode connector may be electrically connectable to a first electrode connector of a second capacitor having a second monolithic diamond body. The first electrode connector may comprise a simple metal layer, sputtered metal, solder balls, or a combination of two or more thereof. The first electrode connector may include one or both of a metal and a conductive resin.

Embodiments described herein may further include a method for manufacturing a capacitor, the method including focusing electromagnetic radiation into a monolithic diamond body to transform a region of the monolithic diamond body into an electrically conductive region comprising conductive carbon, thereby forming a first electrode region within the monolithic diamond body. The method may further include forming a second electrode region within the monolithic diamond body, the second electrode region separated from the first electrode region by a dielectric diamond layer of the monolithic diamond body.

Forming a first electrode region and forming a second electrode region may establish a capacitor unit cell, The method may further include forming a plurality of capacitor unit cells within the monolithic diamond body. Focusing electromagnetic radiation into a monolithic diamond body comprises shaping a laser beam to create a Bessel focus. Focusing electromagnetic radiation into a monolithic diamond body may include shaping a laser beam to create a Gaussian focus. Focusing electromagnetic radiation into a monolithic diamond body may include focusing pulsed electromagnetic radiation into the monolithic diamond body. Focusing electromagnetic radiation into a monolithic diamond body to transform a region of the monolithic diamond body into an electrically conductive region may include conductive carbon, thereby forming a first electrode region within the monolithic diamond body may include forming a first electrode contact region at a surface of the monolithic diamond body, and the first electrode contact region may be adjacent and electrically connected to the first electrode region.

The method may further include forming an electrode connector electrically connected to the first electrode region. The electrode connector may include one or both of a metal and a conductive resin. Forming an electrode connector may include sputtering a metal. Forming an electrode connector may include applying a photolithographic mask on the surface of the monolithic diamond body.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF DRAWINGS

FIG. 1 is a cross-section side view of an illustrative capacitor having one unit cell.

FIG. 2 is a cross-section side view of an illustrative capacitor having three capacitor unit cells.

FIG. 3A is a cross-section side view of an illustrative capacitor having a plurality of unit cells.

FIG. 3B is a perspective view of the illustrative capacitor of FIG. 3A.

FIG. 4A is a cross-section top view of an illustrative cylindrical capacitor.

FIG. 4B is a cross-section side view of the illustrative cylindrical capacitor of FIG. 4A.

FIG. 5A is a cross-section side view of an illustrative capacitor having wedge-shaped electrodes.

FIG. 5B is a cross-section top view of the illustrative capacitor of FIG. 5A.

FIGS. 6A-C are cross-section top views of illustrative ring-shaped capacitors.

FIG. 7A is a cross-section side view of an illustrative capacitor with electrode contact regions each having widths approximately equal to widths of respective electrode regions.

FIGS. 7B-C are cross-section front views of the illustrative capacitor of FIG. 7A.

FIG. 8A is a cross-section side view of an illustrative capacitor with electrode contact regions each having widths less than widths of respective electrode regions.

FIGS. 8B-C are cross-section front views of the illustrative capacitor of FIG. 8A.

FIG. 9A is a cross-section side view of an illustrative capacitor with electrode contact regions not co-planar with respective electrode regions.

FIG. 9B is a cross-section top view of the illustrative capacitor of FIG. 9A.

FIG. 10 is a cross-section side view of an illustrative capacitor with electrode connectors.

FIG. 11 is a cross-section side view of an illustrative capacitor apparatus including the capacitor of FIG. 10 electrically connected to another capacitor via one of the electrode connectors.

FIGS. 12A-B are flow diagrams of an illustrative method of making a capacitor.

FIGS. 13A-D and 14A-B are diagrams illustrating aspects of the illustrative method of FIGS. 12A-B.

The figures are rendered primarily for clarity and, as a result, are not necessarily drawn to scale. Moreover, various structure/components may be shown diagrammatically or removed from some or all of the views to better illustrate aspects of the depicted embodiments, or where inclusion of such structure/components is not necessary to an understanding of the various illustrative embodiments described herein. The lack of illustration/description of such structures/components in a particular figure is, however, not to be interpreted as limiting the scope of the various embodiments in any way.

### DETAILED DESCRIPTION

All scientific and technical terms used herein have meanings commonly used in the art unless otherwise specified. The definitions provided herein are to facilitate understanding of certain terms used frequently herein and are not meant to limit the scope of the present disclosure.

Unless otherwise indicated, the terms “polymer”, “polymerized monomers”, and “polymeric material” include, but are not limited to, organic homopolymers, copolymers, such as for example, block, graft, random and alternating copolymers, terpolymers, etc., and blends and modifications thereof. Furthermore, unless otherwise specifically limited, the term “polymer” shall include all possible geometrical configurations of the material. These configurations include, but are not limited to, isotactic, syndiotactic, and atactic symmetries.

The term “substantially” modifies the term that follows by at least about 90 %, at least about 95%, or at least about 98%. “Substantially” includes “significantly,” which refers to statistical significance.

The term “not substantially” modifies the term that follows by not more than 25%, not more than 10 %, not more than 5%, or not more than 2%.

In this disclosure, all numbers are assumed to be modified by the term “about,” which encompasses the term “exactly.” As used herein in connection with a measured quantity, the term “about” refers to that variation in the measured quantity as would be expected by the skilled artisan making the measurement and exercising a level of care commensurate with the objective of the measurement and the precision of the measuring equipment used.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise. The terms “and/or” and “any combination thereof” and their grammatical equivalents as used herein, can be used interchangeably. These terms can convey that any combination is specifically contemplated. Solely for illustrative purposes, the following phrases “A, B, and/or C” or “A, B, C, or any combination thereof” can mean “A individually; B individually; C individually; A and B; B and C, A and C; and A, B, and C.” The term “or” can be used conjunctively or disjunctively unless the context specifically refers to a disjunctive use.

The recitations of numerical ranges by endpoints include all numbers subsumed within that range (e.g., 1 to 5 includes 1, 1.5, 2, 2.75, 3, 3.80, 4, 5, etc. or 10 or less includes 10, 9.4, 7.6, 5, 4.3, 2.9, 1.62, 0.3, etc.). Where a range of values is “up to”, “at most”, or “at least” a particular value, that value is included within the range.

As used here, “have,” “having,” “include,” “including,” “comprise,” “comprising,” or the like are used in their open-ended sense, and generally mean “including, but not limited to.” It will be understood that “consisting essentially of,” “consisting of,” and the like are subsumed in “comprising” and the like. As used herein, “consisting essentially of,” as it relates to a composition, product, method, or the like, means that the components of the composition, product, method, or the like are limited to the enumerated components and any other components that do not materially affect the basic and novel characteristic(s) of the composition, product, method, or the like.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. It is contemplated that any embodiment discussed in this specification can be implemented with respect to any method or composition of the present disclosure, and vice versa. Furthermore, compositions of the present disclosure can be used to achieve methods of the present disclosure. Such inclusive or open-ended words encompass more restrictive or closed terms or phrases, such as “consisting” or “consisting essentially.”

As used herein, “consisting essentially of” means that the article or method consisting essentially of listed elements may include additional elements that do not materially affect the basic and novel characteristics of the article or method.

The words “preferred” and “preferably” refer to embodiments that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure, including the claims.

Reference in the specification to “some embodiments,” “an embodiment,” “one embodiment,” “embodiments,” “one or more embodiments,” or “other embodiments” means that a particular feature, structure, or characteristic described in connection with the embodiments is included in at least some embodiments, but not necessarily all embodiments, of the present disclosures.

Any direction referred to herein, such as “top,” “bottom,” “left,”“ ” “right,” “upper,” “lower,” and other directions and orientations are described herein for clarity in reference to the figures and are not to be limiting of an actual device or system or use of the device or system. Devices or systems as described herein may be used in a number of directions and orientations.

In several places throughout the application, guidance is provided through examples, which examples, including the particular aspects thereof, can be used in various combinations and be the subject of claims. In each instance, the recited list serves only as a representative group and should not be interpreted as an exclusive list. It is to be understood that the particular examples, materials, amounts, and procedures are to be interpreted broadly in accordance with the scope and spirit of the invention as set forth herein.

Reference will now be made in greater detail to various embodiments of the subject matter of the present disclosure, one or more embodiments of which are illustrated in the accompanying drawings. Like numbers used in the figures refer to like components and steps. However, it will be understood that the use of a number to refer to a component in a given figure is not intended to limit the component in another figure labeled with the same number. In addition, the use of different numbers to refer to components in different figures is not intended to indicate that the different numbered components cannot be the same as or similar to other numbered components.

As described herein, capacitors suitable for small, light-weight form factors and increased durability can be achieved using a monolithic diamond body having capacitor unit cells formed therein by focusing electromagnetic radiation into the monolithic diamond body to convert the diamond into conductive carbon. Such capacitors may reduce the mass and volume required to achieve a given capacitance. That is to say, such capacitors may have improved energy density, improved power density, or both. Additionally, monolithic diamond capacitors may be designed in many different form factors and may be less susceptible to electromechanical deformation and degradation.

As described herein, a diamond capacitor may be formed using a monolithic diamond substrate by selectively converting regions of the diamond substrate into conductive carbon. Using focused electromagnetic radiation, regions of conductive carbon may be formed in the diamond substrate to establish electrodes of the diamond capacitor. The electrodes may be separated by layers of unconverted diamond substrate to establish one or more dielectric layers of the diamond capacitor. Diamond may be described as having a high dielectric strength, allowing energy to be stored in capacitors at higher voltage with reduced volume of dielectric compared to other dielectric materials, such as in electrolytic capacitors. Thus, individual diamond capacitors may also be smaller than individual electrolytic capacitors and still operate at a higher voltage than electrolytic capacitors, as an example.

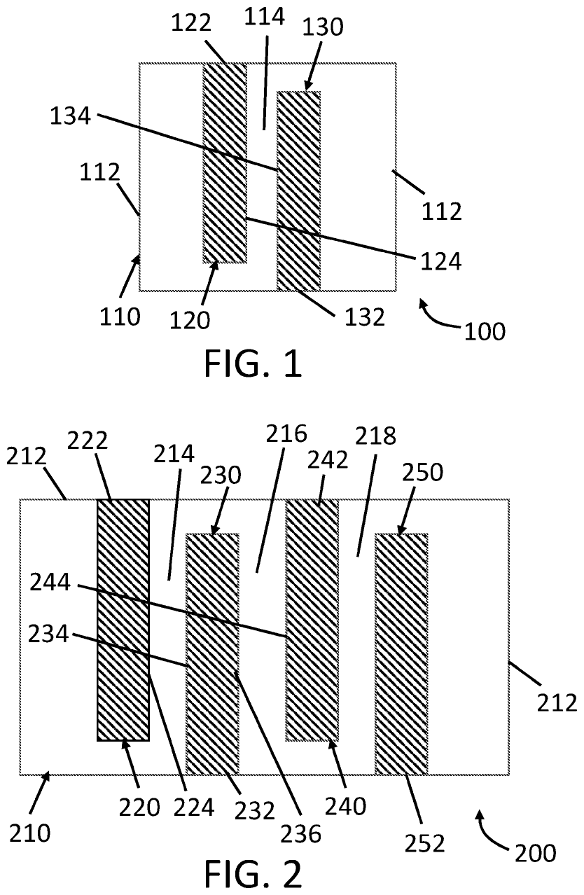

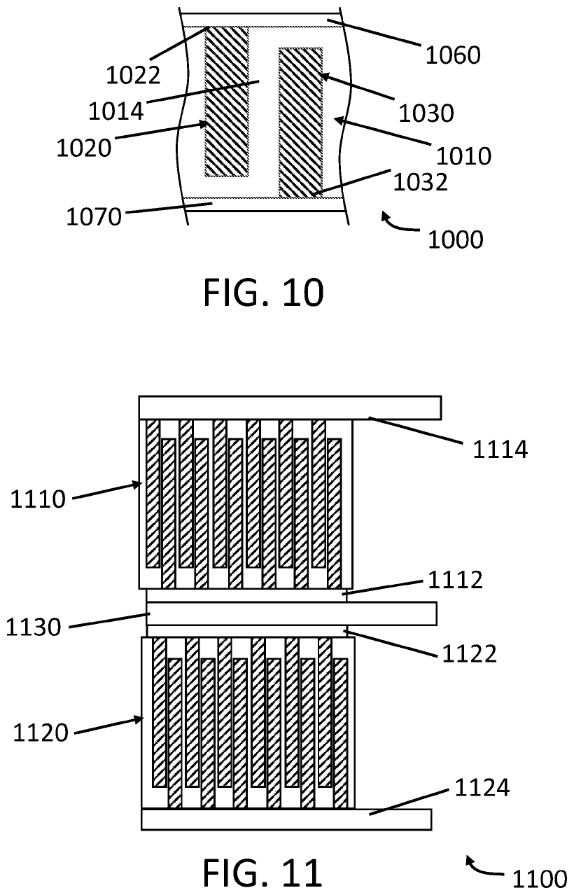

A cross-section side view of an illustrative capacitor 100 is shown in FIG. 1. In one or more embodiments, the capacitor 100 includes a monolithic diamond body 110 having a surface 112. The capacitor 100 may further include a first electrode region 120. The first electrode region 120 may extend from a first electrode contact region 122 at the surface 112 of the monolithic diamond body 110 into the monolithic diamond body 110. The first electrode region 120 may define a plane or an axis. The first electrode contact region may define a plane or an axis, which may be co-planar or co-axial with the plane or the axis defined by the first electrode region. Additionally or alternatively, the plane or axis defined by the first electrode contact region may be not co-planar, not co-axial, or neither co-planar nor co-axial with the plane defined by the first electrode region (see FIGS. 9A-B, for example). The first electrode region 120 may have a polarity, such as a positive polarity or a negative polarity.

The illustrative capacitor 100 may further includes a second electrode region 130. The second electrode region 130 may extend from a second electrode contact region 132 at the outer surface 112 of the monolithic diamond body 110 into the monolithic diamond body 110. The second electrode region 130 may define a plane or an axis, which may be parallel to the plane or the axis of the first electrode region 120. The second electrode region 130 may have a polarity, such as a negative polarity or a positive polarity. The second electrode region 130 may have a polarity opposite the polarity of the first electrode region 120.

A dielectric diamond layer 114 of the monolithic diamond body 110 may separate the first electrode region 120 and the second electrode region 130. The dielectric diamond layer 114 may be described as separating capacitive interface regions 124, 134 of the first electrode region 120 and the second electrode region 130, respectively. The illustrative capacitor 100 may be described as having one capacitor unit cell. That is, the illustrative capacitor 100 may be described as including one dielectric diamond layer 114 separating two electrode regions 120, 130, thereby establishing one capacitor unit cell.

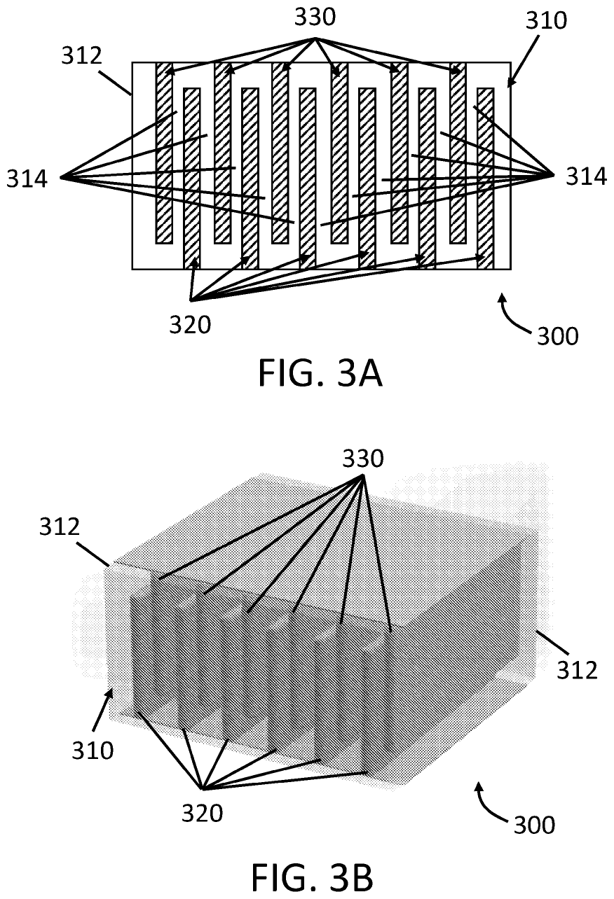

In one or more embodiments, the capacitor may include a plurality of capacitor unit cells. A cross-section side view of an illustrative capacitor 200 having three capacitor unit cells is shown in FIG. 2. The capacitor 200 may include a monolithic diamond body 210 having a surface 212. The capacitor 200 may include a first electrode region 220 extending from a first electrode contact region 222 at the surface 212 into the monolithic diamond body 210. The first electrode region may define a plane or an axis.

The capacitor 200 may further include a second electrode region 230 extending from a second electrode contact region 232 at the surface 212 into the monolithic diamond body 210. The second electrode region may define a plane or an axis, which may be parallel to the plane or the axis defined by the first electrode region. Each of the first and second electrode regions 220, 230 may have a polarity. The first electrode region 220 may have a polarity opposite the polarity of the second electrode region 230. A dielectric diamond layer 214 of the monolithic diamond body 210 may separate the first electrode region 220 and the second electrode region 230. The dielectric diamond layer 214 may be described as separating capacitive interface regions 224, 234 of the first electrode region 220 and the second electrode region 230, respectively.

The capacitor 200 may include a third electrode region 240 extending from a third electrode contact region 242 at the surface 212 into the monolithic diamond body 210. The third electrode region 240 may define a plane or an axis, which may be parallel to the plane or the axis defined by the first electrode region 220. The plane or the axis defined by the third electrode region 240 may additionally or alternatively be parallel to the plane or the axis defined by the second electrode region 230. The third electrode region 240 may have a polarity. The third electrode region 240 may have a polarity opposite the polarity of the second electrode region 230. A second dielectric diamond layer 216 may separate the third electrode region 240 and the second electrode region 230. The second dielectric diamond layer 214 may be described as separating capacitive interface regions 236, 244 of the second electrode region 230 and the third electrode region 240, respectively. The second dielectric diamond layer may be described as establishing a second capacitor unit cell.

The capacitor 200 may further include a fourth electrode region 250 extending from a fourth electrode contact region 252 at the surface 212 into the monolithic diamond body 210. The fourth electrode region 250 may define a plane or an axis, which may be parallel to the plane or the axis defined by the third electrode region 240. The plane or the axis defined by the fourth electrode region 250 may additionally or alternatively be parallel each of to the planes or the axes defined by the first electrode region 220 and the second electrode region 230. The fourth electrode region 250 may have a polarity. The fourth electrode region 250 may have a polarity opposite the polarity of the third electrode region 240. A third dielectric diamond layer 218 may separate the fourth electrode region 250 and the third electrode region 240. The third dielectric diamond layer 218 between the third and fourth electrode regions 240, 250 may be described as establishing a third capacitor unit cell. In one or more embodiments, the capacitor 200 may be described as having interdigitated electrode regions 220, 230, 240, 250 with alternating polarities. Each opposite-polarity pair of electrode regions may be described as establishing a capacitor unit cell.

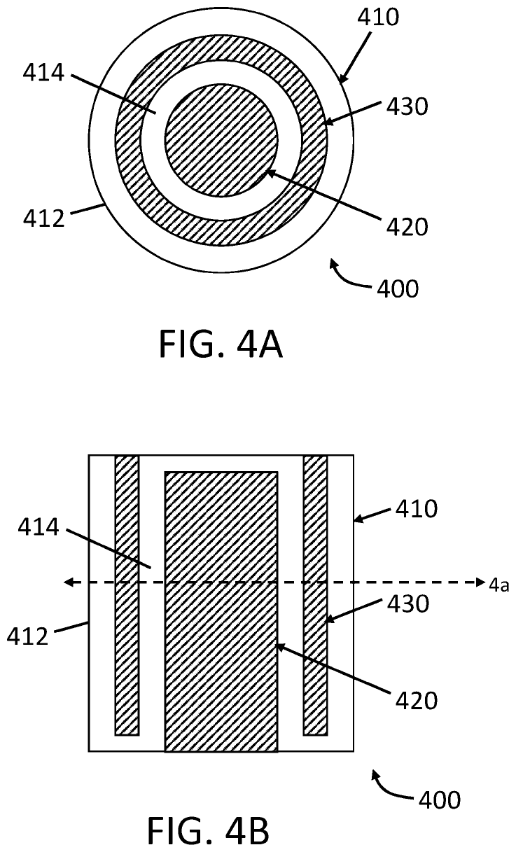

An illustrative capacitor 300 with a plurality of unit cells is shown in cross-section side view in FIG. 3A and in perspective view in FIG. 3B. The plurality of unit cells may be established by a plurality of dielectric diamond layers 314 separating a plurality of interdigitated first electrode regions 320 and second electrode regions 330 extending from respective electrode contact regions at a surface 312 of a monolithic diamond body 310 into the monolithic diamond body 310.

The monolithic diamond body (such as the monolithic diamond body 110, for example) may be described as a single-crystal diamond or as a bulk, single-crystal diamond. The monolithic diamond body may be lab-grown. Additionally or alternatively, the monolithic diamond body may be naturally formed.

The monolithic diamond body may be of any suitable quality. Suitable qualities may include industrial grade diamonds, for example.

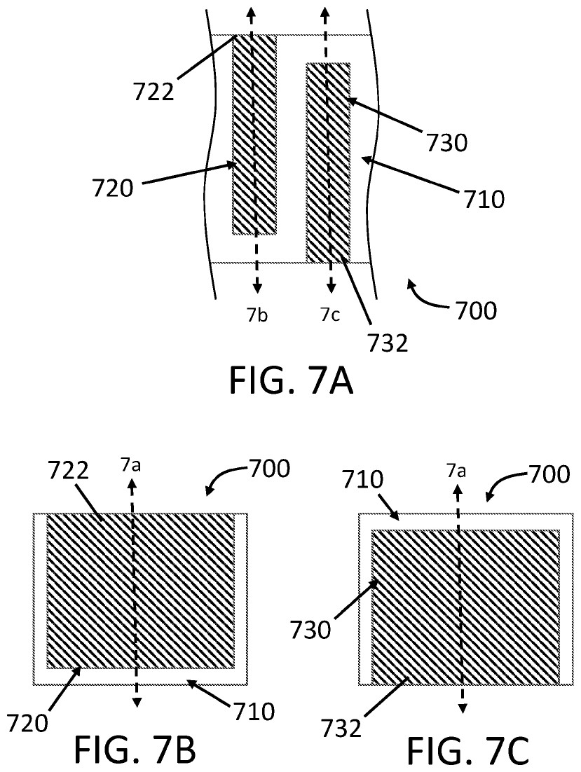

The monolithic diamond body may have any suitable form. Suitable forms may include, for example, a rectangular cross-section, as shown in FIG. 1. Suitable forms may additionally or alternatively include a toric cross-section. Illustrative capacitors 610, 620, 630 having a toric cross-section are each shown in cross-section top view in FIGS. 6A-6C. Further examples of suitable forms may include, but are not limited to, cubic forms, rectangular prism forms, spheric forms, cylindrical forms, toric forms, ring forms, bar forms, rod forms, polygonal forms, or combinations of one or more thereof. It will be understood in light of the present disclosure that any suitable monolithic diamond body form may be used and the disclosure is not limited in this regard.

The monolithic diamond body may be any suitable dimension. The monolithic diamond body may be between 2 centimeters and 6 centimeters wide and between 0.1 centimeters and 0.5 centimeters thick, as an example. In some embodiments, suitable monolithic diamond body dimensions may include a width. For example, the monolithic diamond body width may be between 1 cm and 10 cm. In further examples, the monolithic diamond body width may be more than 0.5 cm, more than 1 cm, more than 2 cm, more than 5 cm, more than 8 cm, or more than 10 cm and/or less than 15 cm, less than 12 cm, less than 10 cm, less than 8 cm, less than 5 cm, less than 3 cm, or less than 1 cm. The monolithic diamond body width may be about 4 cm. Embodiments may include a monolithic diamond body height. For example, the monolithic diamond body height may be between 0.05 cm and 1 cm. In further examples, the monolithic diamond body height may be more than 0.05 cm, more than 0.1 cm, more than 0.2 cm, more than 0.5 cm, more than 0.8 cm, or more than 1 cm and/or less than 1.5 cm, less than 1.2 cm, less than 1 cm, less than 0.8 cm, less than 0.5 cm, less than 0.3 cm, or less than 0.1 cm. The monolithic diamond body height may be about 0.3 cm. One or more embodiments may include a monolithic diamond body depth. For example, the monolithic diamond body depth may be between 0.5 cm and 5 cm. In further examples, the monolithic diamond body depth may be more than 0.5 cm, more than 1 cm, more than 2 cm, more than 5 cm, or more than 8 cm, and/or less than 10 cm, less than 7 cm, less than 5 cm, less than 3 cm, less than 2 cm, less than 1 cm, or less than 0.5 cm. The monolithic diamond body depth may be about 2 cm. It will be understood in light of the present disclosure that any suitable monolithic diamond body dimensions may be used and the disclosure is not limited in this regard.

The monolithic diamond body may be any suitable volume. Suitable monolithic diamond body volumes may include, for example, between 0.1 cubic cm and 10 cubic cm. In further examples, the monolithic diamond body volume may be more than 0.1 cubic cm, more than 1 cubic cm, more than 3 cubic cm, more than 5 cubic cm, more than 8 cubic cm, or more than 10 cubic cm and/or less than 15 cubic cm, less than 12 cubic cm, less than 8 cubic cm, less than 6 cubic cm, less than 3 cubic cm, less than 1 cubic cm, or less than 0.5 cubic cm. The monolithic diamond body volume may be about 2 cubic cm. It will be understood in light of the present disclosure that any suitable monolithic diamond body volume may be used and the disclosure is not limited in this regard.

In one or more embodiments, the electrode region (such as electrode regions 120, 130, as examples) includes conductive carbon. Any suitable form of conductive carbon may be used. Suitable forms of conductive carbon may be described as electrically conductive carbon allotropes such as non-diamond carbon allotropes, as an example. Suitable forms of conductive carbon may include carbon allotropes having an sp² hybridized orbital, as an example. As another example, suitable forms of conductive carbon may include conductive allotropes of carbon formed by thermolysis of diamond. Further examples of conductive carbon may include graphene, graphite, carbon nanotubes, amorphous carbon, and combinations of two or more thereof.

In one or more embodiments, conductive carbon may be characterized based on resistivity. Conductive carbon may be characterized by any suitable resistivity. Suitable conductive carbon resistivities may include between 2 microohms per meter (uO/m) and 3,000 uO/m, between 500 uO/m and 800 uO/m, or between 2.5 uO/m and 5 uO/m, for example. Suitable conductive carbon resistivities may additionally or alternatively include less than 5,000 uO/m, less than 500 uO/m, less than 50 uO/m, or less than 5 uO/m.

In some embodiments, conductive carbon may additionally or alternatively be characterized based on conductivity. Conductive carbon may be characterized by any suitable conductivity. Suitable conductive carbon conductivities may include between 1 Siemen per meter (S/m) and 300,000 S/m, between 200 S/m and 2,000 S/m, or between 2 S/m and 300,000 S/m, for example. Suitable conductive carbon conductivities may additionally or alternatively include greater than 1 S/m, greater than 100 S/m, greater than 1,000 S/m, greater than 10,000 S/m, or greater than 100,000 S/m.

The electrode regions may have any suitable form. Suitable forms may be characterized as having one or more capacitive interface regions (e.g., a surface, a face, or an axis) suitable to each be separated from one or more opposing electrode regions by the dielectric diamond layer. For example, as shown in FIG. 1, the cross-section of the electrode region 120 defines a capacitive interface region 124 separated from the opposing electrode region, the electrode region 130, by the dielectric diamond layer 114. Similarly, the cross-section of the electrode region 130 defines a capacitive interface region 134 separated from the opposing electrode region, the electrode region 120, by the dielectric diamond layer 114.

The capacitive interface region of the electrode region (such as capacitive interface regions 124, 134, for example) may have any suitable surface area. Suitable capacitive interface region surface areas may be selected based on factors such as a desired energy density (for example, an interface region with a higher surface area may provide higher energy density), and desired capacitance (which may likewise be improved by a higher surface area), a dielectric constant of the diamond dielectric, and a thickness of the dielectric diamond layer (in other words, the distance between two capacitive interface regions). As another example, capacitive interface region surface area may be selected based on a desired shape for the capacitor form factor.

In some embodiments, suitable electrode region forms may include a plate, which may be described as defining a plane. Additionally or alternatively, suitable electrode region forms may include a rod form, a cylindrical form, a tubular form, a conical form, a frustoconical form, a prismatic form, a torus form, or combinations of one or more thereof. Suitable electrode region forms may additionally or alternatively include cross-sectional profiles such as planar profiles, non-planar profiles, geometric profiles, non-geometric profiles, undulating profiles, wavy profiles, or curved profiles. It will be understood in light of the present disclosure that any suitable electrode region form may be used and the disclosure is not limited in this regard.

In one or more embodiments, the capacitor may include electrode regions having a plate (i.e., plane) form, as shown in FIG. 3B, as an example. In particular embodiments, the first electrode region (for example, one or more of the plurality of first electrode regions 320) may define a first electrode plane parallel to a second electrode plane defined by the second electrode region (for example, one or more of the plurality of respective second electrode regions 330). That is to say, the plane defined by the first electrode region may be parallel to the plane defined by the opposing (i.e., adjacent) second electrode region. Additionally or alternatively, the first electrode plane defined by the first electrode region may be non-parallel to the second electrode plane defined by the second electrode region (see FIG. 6B, for example).

In some embodiments, the first electrode region of one of the plurality of unit cells may define a plane parallel to the plane defined by the first electrode region of another of the plurality of unit cells (see FIG. 6B and FIG. 6C, as examples).

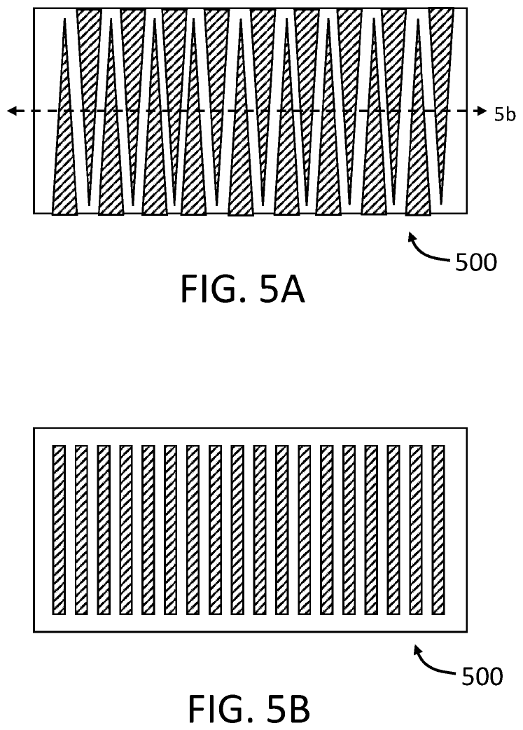

In one or more embodiments, one or both of the first and second electrode regions may each form a ring. In embodiments having ring-shaped electrode regions, the electrode regions may be concentric. An illustrative embodiment of a capacitor 400 with a ring-shaped first electrode concentric to a cylindrical second electrode is shown in FIGS. 4A and 4B. The capacitor 400 may include a first electrode region 420 having a cylindrical form and second electrode region 430 having a tubular form. Such an embodiment may include a tubular diamond dielectric region 414. In some embodiments, the first electrode region 420 may additionally or alternatively have a tubular form. In such embodiments, for example, the first and second electrode may form concentric rings or concentric tubular elements.

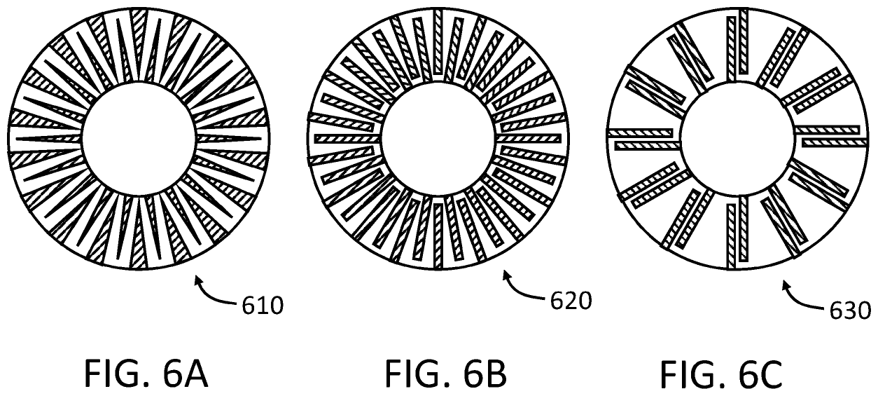

Yet another illustrative embodiment of a capacitor 500 is shown in cross-section side view in FIG. 5A and in cross-section top view in FIG. 5B. The capacitor 500 includes first electrode regions 520 and second electrode regions 530, each having a wedge form (i.e., a triangular prism form or a tapered form). Embodiments including electrode regions having a wedge form may be useful, for example, to reduce resistance in the electrode regions.

The electrode region may have any suitable thickness. Suitable electrode region thicknesses may be selected based on factors such as a desired conductivity (for example, a thicker electrode region may provide higher conductivity than a thinner electrode region), a speed of manufacturing to form each electrode region, and mechanical stresses (on the monolithic diamond substrate, the dielectric diamond layer, and proximate electrode regions, for example), as a few examples. Suitable electrode region thicknesses may include, for example, between 250 nanometers and 2 micrometers. In further examples, the electrode region thickness may be more than 0.5 micrometer, more than 0.8 micrometer, more than 1 micrometer, more than 1.5 micrometer, more than 3 micrometer, or more than 5 micrometer and/or less than 10 micrometer, less than 7 micrometer, less than 5 micrometer, less than 3 micrometer, less than 1 micrometer, or less than 0.5 micrometer. The electrode region layer thickness may be about 1 micrometer. It will be understood in light of the present disclosure that any suitable electrode region layer thickness may be used and the disclosure is not limited in this regard.

The electrode contact region (such as the first electrode contact region 122 and the second electrode contact region 132, as examples) may be described as providing electrical connection between the electrode region and the environment outside the monolithic diamond body (such as the monolithic diamond body 110, for example). As an example, the first electrode contact region 122 may provide electrical connection between the first electrode region 120 and the environment outside the monolithic diamond body 110. As another example, the second electrode contact region 132 may provide electrical connection between the second electrode region 130 and the environment outside the monolithic diamond body 110. The electrode contact region may additionally or alternatively be described as a sub-region of the electrode region at the surface of the monolithic diamond body.

The electrode contact region may have any suitable form. Suitable electrode contact region forms may include a rectangular form, a rod form, a cylindrical form, a tubular form, a conical form, a frustoconical form, a prismatic form, a torus form, or combinations of one or more thereof. It will be understood in light of the present disclosure that any suitable electrode contact region form may be used and the disclosure is not limited in this regard.

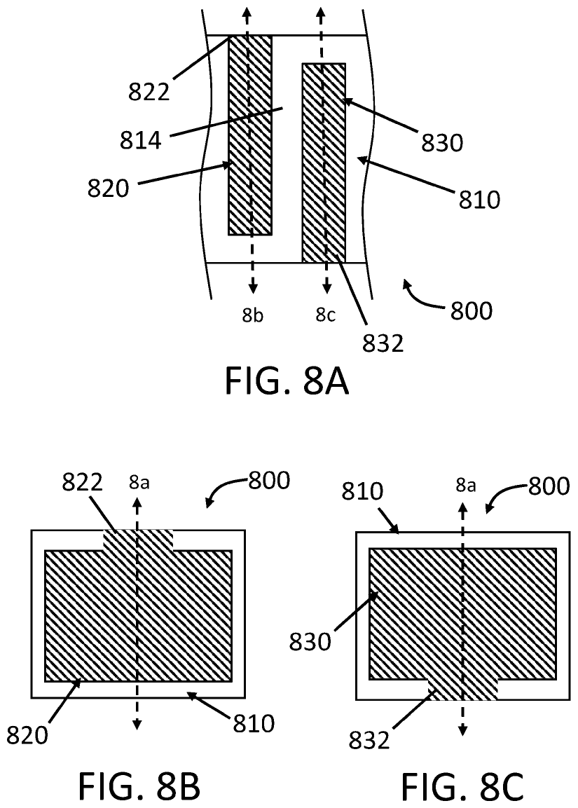

In one or more embodiments, the electrode contact region may have a width that is less than or equal to a width of the electrode contact region's respective electrode region. An illustrative capacitor 700 having electrode contact regions with widths equal to widths of the respective electrode regions is shown in cross-section side view in FIG. 7A.

A front view of the capacitor 700 showing a cross-section (along axis 7b) through a first electrode region 720 is shown in FIG. 7B. In embodiments consistent with aspects of FIG. 7B, a first electrode contact region 722 may have a width approximately equal to a width of the first electrode region 720.

A front view of the capacitor 700 showing a cross-section (along axis 7c) through a second electrode region 730 is shown in FIG. 7C. In embodiments consistent with aspects of FIG. 7C, a second electrode contact region 732 may have a width approximately equal to a width of the second electrode region 730.

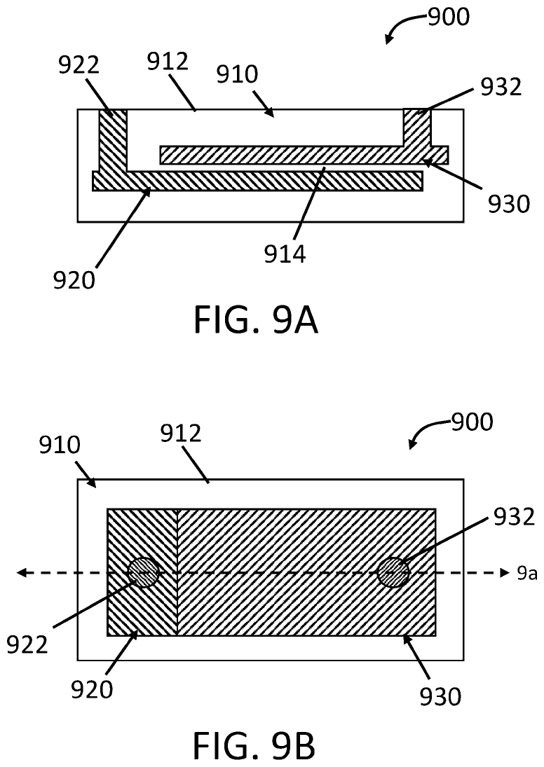

Another illustrative capacitor 800 is shown in cross-section side view in FIG. 8A, the capacitor 800 having electrode contact regions with widths less than widths of the respective electrode regions.

A front view of the capacitor 800 showing a cross-section (along axis 8b) through a first electrode region 820 is shown in FIG. 8B. In embodiments consistent with aspects of FIG. 8B, a first electrode contact region 822 may have a width less than a width of the first electrode region 820.

A front view of the capacitor 800 showing a cross-section (along axis 8c) through a second electrode region 830 is shown in FIG. 8C. In embodiments consistent with aspects of FIG. 8C, a second electrode contact region 832 may have a width approximately equal to a width of the second electrode region 830.

The first and second electrode contact regions (such as electrode contact regions 122, 132, for example) may be at any suitable surface of the monolithic diamond body.

The first and second electrode contact regions may be at the surface of the monolithic diamond body on opposing sides of the monolithic diamond body, as an example (such as shown in FIG. 1). As another example, the first and second electrode contact regions may be at the surface of the monolithic diamond body on the same side of the monolithic diamond body. An illustrative capacitor 900 is shown in cross-section side view in FIG. 9A and in top view in FIG. 9B. The capacitor 900 may include a first electrode region 920 extending from a first electrode contact region 922 at a surface 912 of a monolithic body 910 into the monolithic body 910. In some embodiments, the capacitor 900 may include a second electrode region 930 extending from a second electrode contact region 932 at the surface 912 of the monolithic body 910 into the monolithic body 910. A dielectric diamond layer 914 of the monolithic diamond body may separate the first electrode region 920 from the second electrode region 930. In embodiments consistent with aspects of FIGS. 9A and 9B, one or both of the electrode contact regions 922, 932 may have a cylindrical form.

It will be understood in light of the present disclosure that the electrode contact regions may be at any suitable surface of the monolithic diamond body and the disclosure is not limited in this regard.

The dielectric diamond layer (such as dielectric diamond layer 114, as an example) may have any suitable breakdown voltage. Suitable dielectric diamond layer breakdown voltages may include, for example, between 10 and 100 megavolts per centimeter (MV/cm). In further examples, the dielectric diamond layer breakdown voltage may be more than 10 MV/cm, more than 20 MV/cm, more than 35 MV/cm, more than 50 MV/cm, more than 80 MV/cm, or more than 100 MV/cm and/or less than 120 MV/cm, less than 100 MV/cm, less than 80 MV/cm, less than 65 MV/cm, less than 50 MV/cm, or less than 140 MV/cm. The dielectric diamond layer breakdown voltage may be about 30 MV/cm. It will be understood in light of the present disclosure that any suitable dielectric diamond layer breakdown voltage may be used and the disclosure is not limited in this regard.

The dielectric diamond layer may have any suitable dielectric constant. Suitable dielectric diamond layer dielectric constants may include, for example, between 4 and 10. In further examples, the dielectric diamond layer dielectric constant may be more than 4, more than 5, more than 6, more than 7, more than 8, or more than 9 and/or less than 10, less than 9, less than 8, less than 7, less than 6, or less than 4. The dielectric diamond layer dielectric constant may be about 5.5. It will be understood in light of the present disclosure that any suitable dielectric diamond layer dielectric constant may be used and the disclosure is not limited in this regard.

The dielectric diamond layer may have any suitable thickness. Suitable dielectric diamond layer thicknesses may be selected based on a desired energy density (which may be improved, for example, by minimizing thickness of the dielectric diamond layer), a desired durability (which may be reduced, for example, with lower thickness of the dielectric diamond layer), and a dielectric constant of the dielectric diamond layer, as a few examples. Suitable dielectric diamond layer thicknesses may include, for example, between 250 nanometers and 2 micrometers. In further examples, the dielectric diamond layer thickness may be more than 0.25 micrometers, more than 0.5 micrometers, more than 0.8 micrometers, more than 1 micrometer, more than 1.5 micrometers, more than 3 micrometers, or more than 5 micrometers and/or less than 10 micrometers, less than 7 micrometers, less than 5 micrometers, less than 3 micrometers, less than 1 micrometer, or less than 0.5 micrometers. The dielectric diamond layer thickness may be about 1 micrometer. It will be understood in light of the present disclosure that any suitable dielectric diamond layer thickness may be used and the disclosure is not limited in this regard.

In some embodiments, the dielectric diamond layer may have a consistent thickness across the surface area of the dielectric diamond layer (see FIG. 3B and FIG. FIGS. 5A-B, for examples). Additionally or alternatively, the dielectric diamond layer may have uneven (such as tapered, for example) thickness across the surface area of the dielectric diamond layer (see FIG. 6B, for example).

In one or more embodiments, the capacitor may include a first electrode connector, which may electrically connect at least two first electrode regions of the plurality of capacitor unit cells. Additionally or alternatively, the capacitor may include a second electrode connector, which may electrically connect at least two second electrode regions of the plurality of capacitor unit cells. The first or second electrode connector may each be electrically connectable to a power source (such as a battery or another capacitor, as just two examples) for transfer of energy from the power source to the capacitor. Additionally or alternatively, the first or second electrode connector may each be electrically connectable to a device (such as the leads of a medical device, for example) for transfer of energy from the capacitor to the leads.

The electrode connector may include any suitable material. Suitable electrode connector materials may be selected based on conductivity of the material, a desired method of assembly, and a material compatibility (such as between the electrode connector and the electrode region or between the electrode connector and the monolithic diamond substrate), as a few examples. As another example, suitable materials may be selected based on compatibility of the material with the conductive carbon of the electrode regions. Compatibility may include factors such as contact resistance between the electrode connector material and the conductive carbon or adhesion between the electrode connector material and the conductive carbon. Suitable electrode connector materials may include a metal, a conductive resin, a conductive epoxy (such as an epoxy impregnated with silver), a conductive polymer, or combinations of two or more thereof, for example. As further examples, suitable electrode connector materials may include aluminum, copper, silver, gold, platinum or combinations of two or more thereof. As still further examples, suitable electrode connector materials may include a simple metal layer, sputtered metal, solder balls, or a combination of two or more thereof. It will be understood in light of the present disclosure that any suitable electrode connector material may be used and the disclosure is not limited in this regard.

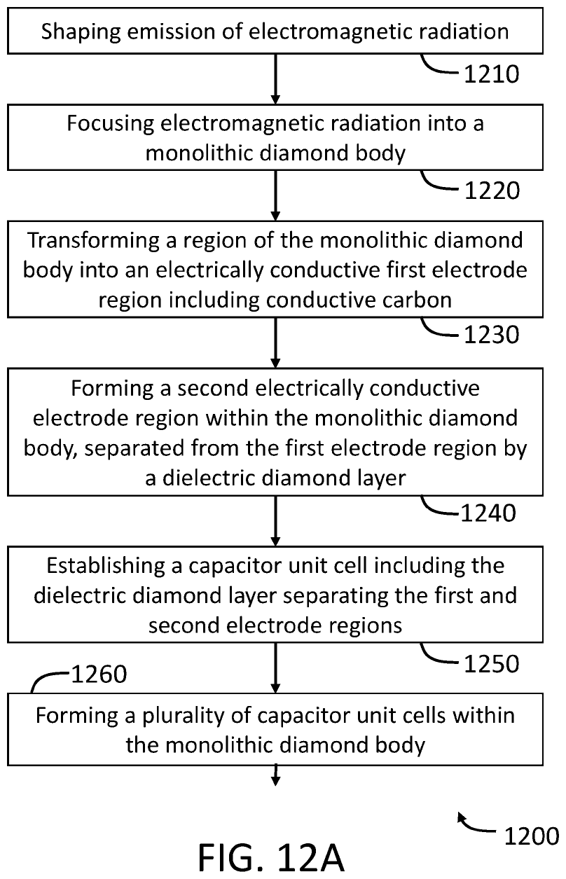

A cross-section side view of an illustrative capacitor 1000 with electrode connectors is shown in FIG. 10. The capacitor 1000 may include a plurality of first electrode regions 1020, each extending from one of a plurality of first electrode contact regions 1022 at a surface 1012 of a monolithic diamond body 1010 into the monolithic diamond body 1010. The capacitor 1000 may further include a plurality of second electrode regions 1030, each extending from one of a plurality of second electrode contact regions 1032 at the surface 1012 of the monolithic diamond body 1010 into the monolithic diamond body 1010. Embodiments consistent with aspects of the capacitor 1000 may include a first electrode connector 1060 and a second electrode connector 1070. The first electrode connector 1060 may be electrically connectable to at least one of the plurality of first electrode regions 1020 via the first electrode contact region 1022 of the respective first electrode region 1020. The second electrode connector 1070 may be electrically connectable to at least one of the plurality of second electrode regions 1030 via the second electrode contact region 1032 of the respective second electrode region 1030.

In one or more embodiments, the first electrode connector may be electrically connectable to a first electrode connector of another capacitor. Likewise, the second electrode connector may be electrically connectable to a second electrode connector of another capacitor. That is to say, two or more capacitors may be electrically connectable via their respective first and second electrode connectors. For example, a plurality of capacitors may be electrically connectable in parallel, in series, or in a combination thereof.

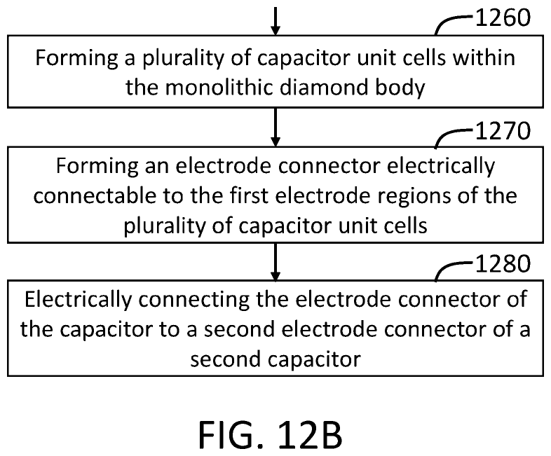

A cross-section side view of an illustrative assembly 1100 of two capacitors is shown in FIG. 11. The assembly 1100 may include a first capacitor 1110 and a second capacitor 1120. The first capacitor 1110 may have one or both of a first electrode connector 1112 and a second electrode connector 1114. Similarly, the second capacitor 1120 may have one or both of a first electrode connector 1122 and a second electrode connector 1124. The first electrode connector 1112 of the first capacitor 1110 may be electrically connectable to the first electrode connector 1122 of the second capacitor 1120, for example, via an optional bridge 1130. The bridge 1130 may include any suitable material. Suitable bridge materials may include one or more of the suitable electrode connector materials discussed in the present disclosure. It will be understood in light of the present disclosure that any suitable bridge material may be used and the disclosure is not limited in this regard.

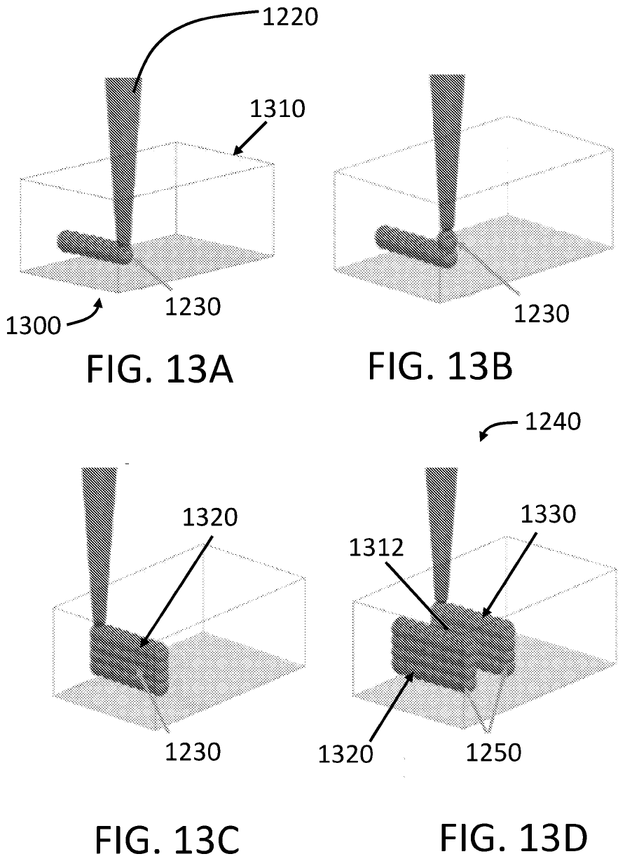

A flow diagram illustrating a method 1200 of making a capacitor according to the present disclosure is shown in FIG. 12A. It is noted that the operations associated with the methods disclosed herein are not particularly limited to the order reflected in FIG. 12A.

The method 1200 may include focusing electromagnetic radiation 1220 into a monolithic diamond body, thereby transforming a region of the monolithic diamond body 1230 into an electrically conductive region including conductive carbon. The focusing electromagnetic radiation 1220 may include focusing a pulsed laser (for example, an ultrafast-pulsed laser) into the monolithic diamond body to transform targeted regions of the diamond into conductive regions of conductive carbon. The transforming a region of the monolithic diamond body 1230 into an electrically conductive region may include forming an electrically conductive first electrode region within the monolithic diamond body.

The focusing electromagnetic radiation 1220 may include forming a first electrode contact region at a surface of the monolithic diamond body. The first electrode contact region may be adjacent or electrically connected to the first electrode region, or a combination thereof.

The focusing electromagnetic radiation 1220 may include shaping electromagnetic radiation 1210, such as a laser beam, to create a Gaussian Focus. For example, Gaussian laser pulses may be focused inside the monolithic diamond body. A Gaussian focus may be described as exhibiting a relatively shallow axial depth of focus, which may be approximately the same size as the lateral extent of focus. In other words, a Gaussian focus may be described as having a low aspect ratio.

The focusing electromagnetic radiation 1220 may additionally or alternatively include shaping electromagnetic radiation 1210, such as a laser beam, to create a Bessel Focus. For example, Bessel laser pulses may be focused inside the monolithic diamond body. A Bessel focus may be described as exhibiting a relatively deep axial depth of focus, which may be up to hundreds of times longer than the lateral extent of the focus. In other words, a Bessel focus may be described as forming a cylindrical focal region conceptually similar to a pencil. Put another way, a Bessel focus may be described as having a low aspect ratio. Although the rays of the Bessel laser may be described as converging across a wide lateral extent, the energy intensity may be described as reaching the threshold for transforming the diamond monolithic body only in the centermost 1-2 micrometers of the overlap region.

In some embodiments, the method 1200 may include forming 1240 a second electrically conductive electrode region within the monolithic diamond body. The second electrode region may be formed, for example, by focusing 1220 electromagnetic radiation into the monolithic diamond body. The second electrode region may include conductive carbon formed by diamond thermolysis. The second electrode region may be separated from the first electrode region by a dielectric diamond layer, as described herein.

In one or more embodiments, the method 1200 may include establishing a capacitor unit cell 1250 including the dielectric diamond layer separating the first and second electrode regions.

In some embodiments, the method 1200 may include forming a plurality of capacitor unit cells 1260 within the monolithic diamond body. The forming a plurality of capacitor unit cells 1260 within the monolithic diamond body may include forming interdigitated first and second electrode regions.

The flow diagram illustrating the method 1200 of making a capacitor according to the present disclosure is continued in FIG. 12B. It is noted that the operations associated with the methods disclosed herein are not particularly limited to the order reflected in FIG. 12B.

In some embodiments, the method 1200 may include forming an electrode connector 1270 electrically connectable to the first electrode region of at least one of the plurality of capacitor unit cells. The forming an electrode connector 1270 electrically connectable to the first electrode region of at least one of the plurality of capacitor unit cells may include forming an electrode connector electrically connected to the first electrode region of at least one of the plurality of capacitor unit cells. The forming an electrode connector 1270 may include applying a photolithographic mask on the surface of the monolithic diamond body, for example.

In one or more embodiments, the method 1200 may include electrically connecting 1280 the electrode connector of the capacitor to a second electrode connector of a second capacitor.

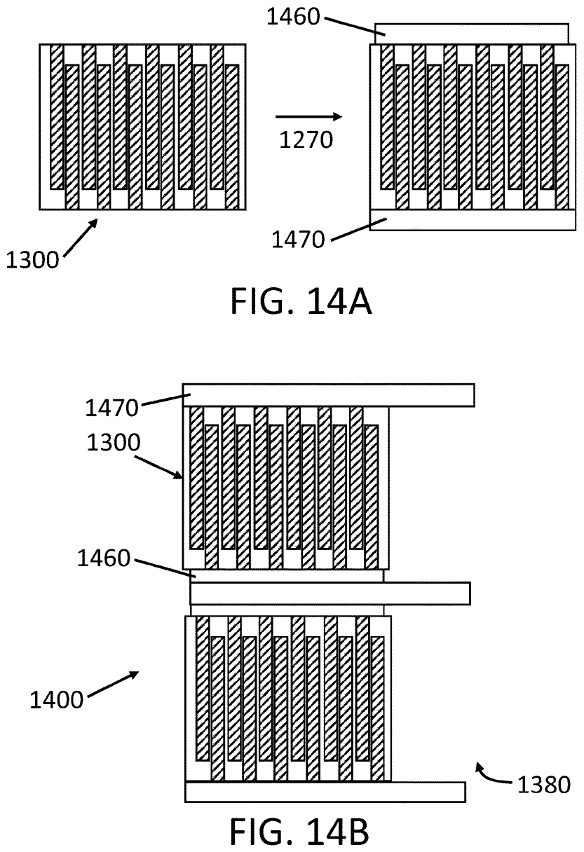

A diagram illustrating aspects of the method 1200 of making a capacitor 1300 according to the present disclosure is shown in FIGS. 13A-D. As described herein, the method 1200 may include the focusing electromagnetic radiation 1220 into a monolithic diamond body 1310, thereby transforming 1230 a region of the monolithic diamond body 1310 into an electrically conductive region including conductive carbon. The transforming 1230 a region of the monolithic diamond body 1310 into an electrically conductive region may include forming a first electrode region 1320 within the monolithic diamond body 1310. In some embodiments, as described herein, the method 1200 may include the forming 1240 a second electrode region 1330 within the monolithic diamond body 1310. In one or more embodiments, the method 1200 may include the establishing a capacitor unit cell 1250 including a dielectric diamond layer 1312 separating the first and second electrode regions 1320, 1330.

A diagram illustrating aspects of the method 1200 of making a capacitor assembly 1400 according to the present disclosure is shown in FIGS. 14A-B. As described herein, the method 1200 may include the forming 1270 an electrode connector 1460 electrically connectable to the first electrode region of at least one of the plurality of capacitor unit cells. The method 1200 may further include forming a second electrode connector 1470 electrically connectable to the second electrode region of at least one of the plurality of capacitor unit cells. As described herein, the method 1200 may still further include electrically connecting 1280 the electrode connector 1460 of the capacitor 1300 to a second electrode connector of a second capacitor, thereby forming the capacitor assembly 1400.

### Illustrative Aspects

The following is a list of illustrative embodiments according to the present disclosure.

Aspect 1 is a capacitor comprising:

a monolithic diamond body comprising:

a first electrode region comprising conductive carbon extending from a first electrode contact region at an outer surface of the monolithic diamond body into the monolithic diamond body;

a second electrode region comprising conductive carbon extending from a second electrode contact region at the outer surface of the monolithic diamond body into the monolithic diamond body; and

a dielectric diamond layer of the monolithic diamond body separating the first electrode region and the second electrode region.

Aspect 2 is the capacitor of any one of aspects 1 and 3-16, wherein one or both of the first and second electrode regions each define a plane.

Aspect 3 is the capacitor of any one of aspects 1-2 and 4-16, wherein the first electrode region defines a first electrode plane and the second electrode region defines a second electrode plane parallel to the first electrode plane.

Aspect 4 is the capacitor of aspects 3, wherein the first electrode contact region defines a first electrode contact plane co-planar with the first electrode plane.

Aspect 5 is the capacitor of any one of aspects 1-4 and 6-16, wherein one or both of the first and second electrode regions each defines a ring.

Aspect 6 is the capacitor of any one of aspects 1-5 and 7-16, wherein the first electrode region defines a first electrode ring and the second electrode region defines a second electrode ring concentric to the first electrode ring.

Aspect 7 is the capacitor of any one of aspects 1-6 and 8-16, wherein one or both of the first and second electrode regions each defines an axis.

Aspect 8 is the capacitor of any one of aspects 1-7 and 9-16, wherein the first electrode region defines a first electrode axis and the second electrode region defines a second electrode axis parallel to the first electrode axis.

Aspect 9 is the capacitor of aspect 8, wherein the first electrode contact region defines a first electrode contact axis co-axial with the first electrode axis.

Aspect 10 is the capacitor of any one of aspects 1-8 and 10-16, further comprising:

a third electrode region extending from a third electrode contact region at the outer surface of the monolithic diamond body into the monolithic diamond body;

a fourth electrode region extending from a fourth electrode contact region at the outer surface of the monolithic diamond body into the monolithic diamond body; and

a second dielectric diamond layer of the monolithic diamond body separating the third electrode region and the fourth electrode region.

Aspect 11 is the capacitor of aspect 10, wherein the first electrode region defines a first electrode plane, and the third electrode region defines a third electrode plane parallel to the first electrode plane.

Aspect 12 is the capacitor of any one of aspects 1-11 and 13-16, wherein the first electrode region and the second electrode region are of opposite polarities.

Aspect 13 is the capacitor of any one of aspects 1-12 and 14-16, wherein a width of the first electrode region is greater than or equal to a width of the first electrode contact region.

Aspect 14 is the capacitor of any one of aspects 1-13 and 15-16, wherein a thickness of the dielectric diamond layer is between 250 nanometers and 2 micrometers.

Aspect 15 is the capacitor of any one of aspects 1-14 and 16, wherein a thickness of the first electrode region and a thickness of the second electrode region are each between 250 nanometers and 2 micrometers.

Aspect 16 is the capacitor of any one of aspects 1-15, wherein a width of the monolithic diamond body is between 2 centimeters and 6 centimeters and wherein a thickness of the monolithic diamond body is between 0.1 centimeters and 0.5 centimeters.

Aspect 17 is a capacitor comprising:

a monolithic diamond body; and
a plurality of capacitor unit cells, each unit cell comprising:

a first electrode region comprising conductive carbon extending from a first electrode contact region at an outer surface of the monolithic diamond body into the monolithic diamond body;

a second electrode region comprising conductive carbon extending from a second electrode contact region at the outer surface of the monolithic diamond body into the monolithic diamond body; and

a dielectric diamond layer of the monolithic diamond body separating the first electrode region and the second electrode region.

Aspect 18 is the capacitor of any one of aspects 17 and 19-22, wherein the first electrode region of at least one of the plurality of capacitor unit cells is the second electrode region of another one of the plurality of capacitor unit cells.

Aspect 19 is the capacitor of claim any one of aspects 17-18 and 20-22, further comprising a first electrode connector electrically connecting at least two first electrode regions of the plurality of capacitor unit cells.

Aspect 20 is the capacitor of aspect 19, wherein the first electrode connector is electrically connectable to a first electrode connector of a second capacitor comprising a second monolithic diamond body.

Aspect 21 is the capacitor of any one of aspects 17-20 and 22, wherein the first electrode connector comprises a simple metal layer, sputtered metal, solder balls, or a combination of two or more thereof.

Aspect 22 is the capacitor of any one of aspects 17-21, wherein the first electrode connector comprises one or both of a metal and a conductive resin.

Aspect 23 is a method for manufacturing a capacitor, the method comprising: focusing electromagnetic radiation into a monolithic diamond body to transform a region of the monolithic diamond body into an electrically conductive region comprising conductive carbon, thereby forming a first electrode region within the monolithic diamond body; and

forming a second electrode region within the monolithic diamond body, the second electrode region separated from the first electrode region by a dielectric diamond layer of the monolithic diamond body.

Aspect 24 is the method of any one of aspects 23 and 25-32, wherein forming a first electrode region and forming a second electrode region establishes a capacitor unit cell, the method further comprising forming a plurality of capacitor unit cells within the monolithic diamond body.

Aspect 25 is the method of any one of aspects 23-24 and 26-32, wherein focusing electromagnetic radiation into a monolithic diamond body comprises shaping a laser beam to create a Bessel focus.

Aspect 26 is the method of any one of aspects 23-25 and 27-32, wherein focusing electromagnetic radiation into a monolithic diamond body comprises shaping a laser beam to create a Gaussian focus.

Aspect 27 is the method of any one of aspects 23-26 and 28-32, wherein focusing electromagnetic radiation into a monolithic diamond body comprises focusing pulsed electromagnetic radiation into the monolithic diamond body.

Aspect 28 is the method of any one of aspects 23-27 and 29-32, wherein focusing electromagnetic radiation into a monolithic diamond body to transform a region of the monolithic diamond body into an electrically conductive region comprising conductive carbon, thereby forming a first electrode region within the monolithic diamond body comprises forming a first electrode contact region at a surface of the monolithic diamond body, the first electrode contact region adjacent and electrically connected to the first electrode region.

Aspect 29 is the method of any one of aspects 23-28 and 30-32, further comprising forming an electrode connector electrically connected to the first electrode region.

Aspect 30 is the method of any one of aspects 29 and 31-32, wherein the electrode connector comprises one or both of a metal and a conductive resin.

Aspect 31 is the method of any one of aspects 29-30 and 32, wherein forming an electrode connector comprises sputtering a metal.

Aspect 32 is the method of any one of aspects 29-31, wherein forming an electrode connector comprises applying a photolithographic mask on the surface of the monolithic diamond body.

It should also be noted that, as used in this specification and the appended claims, the phrase “configured” describes a system, apparatus, or other structure that is constructed to perform a particular task or adopt a particular configuration. The word “configured” can be used interchangeably with similar words such as “arranged”, “constructed”, “manufactured”, and the like.

All publications and patent applications in this specification are indicative of the level of ordinary skill in the art to which this technology pertains. All publications and patent applications are herein incorporated by reference to the same extent as if each individual publication or patent application was specifically and individually indicated by reference. In the event that any inconsistency exists between the disclosure of the present application and the disclosure(s) of any document incorporated herein by reference, the disclosure of the present application shall govern.

This application is intended to cover adaptations or variations of the present subject matter. It is to be understood that the above description is intended to be illustrative, and not restrictive, and the claims are not limited to the illustrative embodiments as set forth herein.

1. A capacitor comprising:
a monolithic diamond body comprising:
a first electrode region comprising conductive carbon extending from a first electrode contact region at an outer surface of the monolithic diamond body into the monolithic diamond body;
a second electrode region comprising conductive carbon extending from a second electrode contact region at the outer surface of the monolithic diamond body into the monolithic diamond body; and
a dielectric diamond layer of the monolithic diamond body separating the first electrode region and the second electrode region.

2. The capacitor of claim 1, wherein one or both of the first and second electrode regions each define a plane.

3. The capacitor of claim 1, wherein the first electrode region defines a first electrode plane and the second electrode region defines a second electrode plane parallel to the first electrode plane.

4. The capacitor of claim 3, wherein the first electrode contact region defines a first electrode contact plane co-planar with the first electrode plane.

5. The capacitor of claim 1, wherein one or both of the first and second electrode regions each defines a ring.

6. The capacitor of claim 1, wherein the first electrode region defines a first electrode ring and the second electrode region defines a second electrode ring concentric to the first electrode ring.

7. The capacitor of claim 1, wherein the first electrode region defines a first electrode axis and the second electrode region defines a second electrode axis parallel to the first electrode axis.

8. The capacitor of claim 7, wherein the first electrode contact region defines a first electrode contact axis co-axial with the first electrode axis.

9. The capacitor of claim 1, further comprising:
a third electrode region extending from a third electrode contact region at the outer surface of the monolithic diamond body into the monolithic diamond body;
a fourth electrode region extending from a fourth electrode contact region at the outer surface of the monolithic diamond body into the monolithic diamond body; and
a second dielectric diamond layer of the monolithic diamond body separating the third electrode region and the fourth electrode region.

10. The capacitor of claim 10, wherein the first electrode region defines a first electrode plane, and the third electrode region defines a third electrode plane parallel to the first electrode plane.

11. The capacitor of claim 1, wherein a thickness of the dielectric diamond layer is between 250 nanometers and 2 micrometers, and wherein a thickness of the first electrode region and a thickness of the second electrode region are each between 250 nanometers and 2 micrometers.

12. The capacitor of claim 1, wherein a width of the monolithic diamond body is between 2 centimeters and 6 centimeters and wherein a thickness of the monolithic diamond body is between 0.1 centimeters and 0.5 centimeters.

13. A capacitor comprising:
a monolithic diamond body; and
a plurality of capacitor unit cells, each unit cell comprising:
a first electrode region comprising conductive carbon extending from a first electrode contact region at an outer surface of the monolithic diamond body into the monolithic diamond body;
a second electrode region comprising conductive carbon extending from a second electrode contact region at the outer surface of the monolithic diamond body into the monolithic diamond body; and
a dielectric diamond layer of the monolithic diamond body separating the first electrode region and the second electrode region.

14. The capacitor of claim 13, wherein the first electrode region of at least one of the plurality of capacitor unit cells is the second electrode region of another one of the plurality of capacitor unit cells.

15. A method for manufacturing a capacitor, the method comprising:
focusing electromagnetic radiation into a monolithic diamond body to transform a region of the monolithic diamond body into an electrically conductive region comprising conductive carbon, thereby forming a first electrode region within the monolithic diamond body; and
forming a second electrode region within the monolithic diamond body, the second electrode region separated from the first electrode region by a dielectric diamond layer of the monolithic diamond body.

16. The method of claim 15, wherein forming a first electrode region and forming a second electrode region establishes a capacitor unit cell, the method further comprising forming a plurality of capacitor unit cells within the monolithic diamond body.

17. The method of claim 15, wherein focusing electromagnetic radiation into a monolithic diamond body comprises shaping a laser beam to create a Bessel focus.

18. The method of claim 15, wherein focusing electromagnetic radiation into a monolithic diamond body comprises shaping a laser beam to create a Gaussian focus.

19. The method of any of claim 15, wherein focusing electromagnetic radiation into a monolithic diamond body comprises focusing pulsed electromagnetic radiation into the monolithic diamond body.
